(19) United States
(12) Patent Application Publication
(10) Pub. No.: US 2024/0313575 A1
(43) Pub. Date: Sep. 19, 2024

(54) BUILDING ENERGY MANAGEMENT SYSTEM

(71) Applicant: NX CO., LTD., Ulsan (KR)

(72) Inventor: Ju Hyun NAM, Ulsan (KR)

(21) Appl. No.: 18/673,380

(22) Filed: May 24, 2024

Related U.S. Application Data
(63) Continuation of application No. PCT/KR2021/019054, filed on Dec. 15, 2021.

(30) Foreign Application Priority Data
Dec. 15, 2021 (KR) 10-2021-0179384

(51) Int. Cl. H02J 13/00

(52) U.S. Cl. CPC H02J 13/00002

(57) ABSTRACT

The building energy management system includes a first module connected to a first device to generate first pattern data including information related to an energy and a control of the first device; and a server that receives the first pattern data from the first module and controls the first device through the first module based on the first pattern data, wherein the first module is configured to receive a plurality of time information, and a plurality of energy information and a plurality of control information respectively corresponding to the plurality of time information from the first device, classify the plurality of control information according to a control subject, a control location, and a control item for operation of the first device, and generate the first pattern data based on the plurality of energy information and a plurality of classified control information including information related to power of the first device.

### TECHNICAL FIELD

Embodiments of the present disclosure described herein relate to a building energy management system, and more particularly, relate to a building energy management system that collects energy information and control information from devices arranged in a building and establishes a comprehensive energy policy.

### BACKGROUND ART

Recently, many measures to control carbon emissions have been in the spotlight. In relation to carbon emissions, there is a growing need to efficiently consume and manage energy, especially from devices arranged in buildings. There is a need to provide a building energy management system for comprehensively managing the energy of a building by incorporating efficient IoT technology and machine learning technology into devices arranged in the building.

### SUMMARY

### Technical Problem

An aspect of the present disclosure provides a building energy management system that manages the energy of a building by generating pattern data including energy information and control information.

### Advantageous Effects of the Invention

According to the embodiments of the present disclosure, it is possible to provide a building energy management system that manages the energy of a building by generating pattern data including energy information and control information.

### BRIEF DESCRIPTION OF THE DRAWINGS

FIGS. 1A and 1B are diagrams illustrating a device and a module arranged in a building.

FIG. 2 is a diagram illustrating an environment of a building energy management system according to an embodiment.

FIG. 3 is a diagram illustrating pattern data according to an embodiment.

FIG. 4 is a diagram illustrating an example of pattern data according to an embodiment.

FIGS. 5A and 5B are diagrams illustrating control data and delay measurement according to an embodiment.

### DETAILED DESCRIPTIONS OF EXEMPLARY EMBODIMENTS

According to an embodiment, a building energy management system that collects information about a module connected to a device arranged in a building to manage an energy of the building includes a first module connected to a first device to generate first pattern data including information related to an energy and a control of the first device; and a server receives the first pattern data from the first module and controls the first device through the first module based on the first pattern data, wherein the first module is configured to receive a plurality of time information, and a plurality of energy information and a plurality of control information respectively corresponding to the plurality of time information from the first device, classify the plurality of control information according to a control subject, a control location, and a control item for operation of the first device, and generate the first pattern data based on the plurality of energy information and a plurality of classified control information including information related to power of the first device.

In this case, the control subject may include at least one of a person, an application, an external device, and an internal device of the first device.

In this case, the control location may be set based on sensing information from a GPS sensor included in a device when the control subject is the device.

In this case, the plurality of time information may be determined by internal time information of the first module, and the internal time information of the first module may be periodically or aperiodically synchronized by the server.

In this case, the control item may include at least one of power, illuminance, temperature, and humidity of the first device.

In this case, the plurality of energy information may include the plurality of time information and a plurality of power data and arc data respectively corresponding to the plurality of time information, the plurality of power data may include at least one of voltage, current, power amount, and power factor information of the first device, and the arc data may include whether an arc occurs in the first device and an arc current.

In this case, the server may obtain energy information at a first time point, control information at the first time point, energy information at a second time point, and control information at the second time point among data included in the first pattern data, and input energy information and control information for each time point included in the first pattern data to a machine learning model, and analyze reason for control of the first device for each time point based on the machine learning model.

According to an embodiment, an energy management module that is connected to a device arranged in a building to control the device and collects information about the device to transmit collected information to an external device includes a control unit connected to the device to change a power state of the device or adjust a voltage or a current; a storage unit that stores energy information related to an energy of the device and control information for operation of the device; and a communication unit that transmits data including the energy information and the control information to the external device or receives control command data for the device from the external device, wherein the energy information includes at least one of voltage, current, power amount, and power factor information of the device, and the control information includes a control subject, a control location, and a control item for the operation of the device.

Embodiments disclosed in the present disclosure are provided for the sake of descriptions, not limiting the technical concepts of the present disclosure, and it should be understood that such embodiments are not intended to limit the scope of the technical concepts of the present disclosure. The scope of the present disclosure should be construed to include modifications or variations that do not depart from the spirit of the present disclosure.

With respect to the terms used in embodiments of the present disclosure, general terms currently and widely used are selected in view of function with respect to the disclosure. However, the terms may vary according to an intention of a technician practicing in the pertinent art, an advent of new technology, and the like. However, when a specific term is defined and used with an arbitrary meaning, the meaning of the term will be described separately. Accordingly, the terms used in the description should not necessarily be construed as simple names of the terms, but be defined based on meanings of the terms and overall contents of the present disclosure.

The drawings attached to the present disclosure are intended to easily explain embodiments of the present disclosure, and the shapes shown in the drawings may be exaggerated as necessary to aid understanding of the present disclosure, so the present disclosure is not limited by the drawings.

In describing the embodiments of the present disclosure, when a specific description of the related art is deemed to obscure the subject matter of the embodiments of the present disclosure, the detailed description will be omitted.

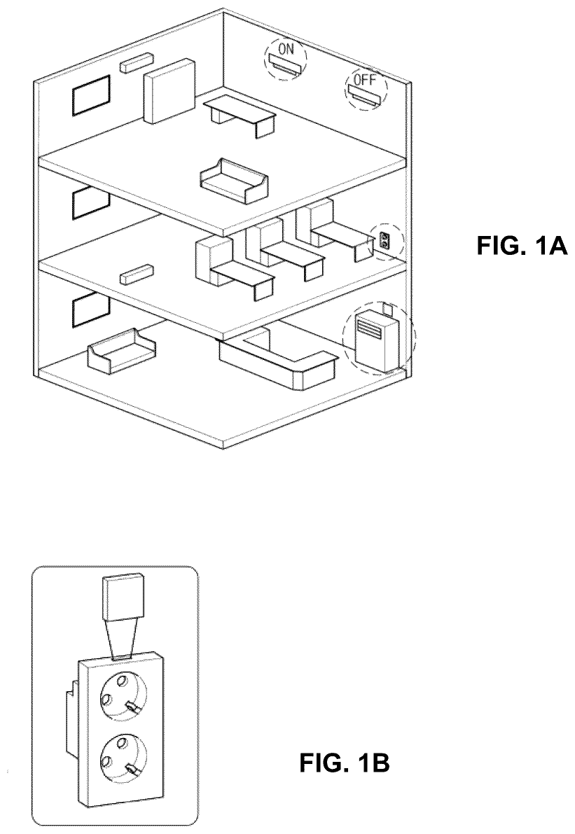

FIG. 1 is a diagram illustrating a device and a module arranged in a building. FIG. 1A is a diagram illustrating a device arranged in a building, and FIG. 1B is a diagram illustrating a module connected to a device.

Referring to FIG. 1A, a plurality of devices arranged in a building are shown. Typically, a plurality of devices including an entry device, a lighting device, a heating/cooling device, a circulation device, and a power supply device are installed inside and outside a building.

The entry device arranged in a building may include a door lock, an entry door lock device, an automatic door device, an automatic revolving door, an authentication device through supplementation, or the like. The lighting device included in a building may include a light emitting device such as a light bulb, an LED light, an emergency light, or the like, illuminance of some of which may be adjusted.

The cooling/heating device arranged in a building may include a device that control indoor temperature, such as an air conditioner, a heating device, a heater, a radiator, and the like, some of which may also control indoor humidity. The circulation device arranged in a building may include a device that can circulate air in the building, such as a circulator, a ventilator, and the like. The power supply device arranged in a building may include a power supply, an outlet, and the like.

Referring to FIG. 1B, a module connected to an outlet arranged in a building is shown. In FIG. 1B, an outlet is used as an example of the device, but a device that can be connected to a module may be each device included in the entry device, lighting device, heating/cooling device, circulation device, and power supply device.

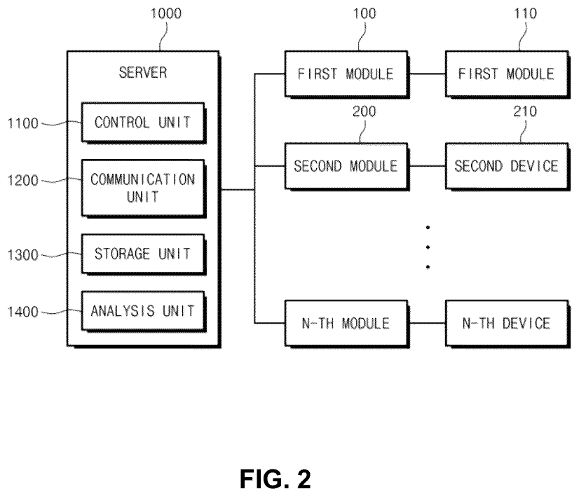

The module may be connected to a device to collect information related to the energy of the device and control the device. In detail, the module may be connected to wires or circuits inside the device to collect data and transmit the collected data to a server. The module will be described in detail with reference to FIG. 2.

FIG. 2 is a diagram illustrating an environment of a building energy management system according to an embodiment.

Referring to FIG. 2, the building energy management system according to an embodiment may include a server 1000, one or more modules, and one or more devices.

As shown in FIG. 1B, modules 100 and 200 may be connected to a device to collect data from the device. In detail, the module may collect information related to the energy of the device.

According to an embodiment, the module may collect voltage, current, power amount, or power factor information of the device. The module may collect the parameters in real time, periodically, or aperiodically by a control command from the server 1000. In addition, the module may collect information about whether arcing occurs in the device and an arc current when arcing occurs.

According to another embodiment, the module may collect information about control of the device. In detail, the module may collect information about who the device is controlled by, at what location, for which item, and with what content.

For example, for a lighting device in a room, the module may collect information about the fact that the lighting device is turned off by a person inside the room at a time point. In addition, for example, for an air conditioner, the module may collect information about the fact that the air conditioner is turned off at a time point through the reservation function of the air conditioner.

In addition, for example, for a heater in a room, the module may collect information about a decrease in the set temperature of the heater by a user terminal outside the room at a time point. In addition, for example, for an outlet in a room, the module may collect information about the fact that the power of the outlet is turned off by an external device at a time point.

The server 1000, which is a central component of the building energy management system, may serve as the overall control unit of the building energy system.

The server 1000 may be connected to the first module 100 and the second module 200. In addition, the server 1000 may be connected to the first module 100 and the second module 200 to exchange communication signals.

Alternatively, when the device has a communication function, the server 1000 may exchange communication signals directly with each device without passing through a module. However, since it is rare for a device to have a communication function, this specification focuses on an example in which the server 1000 collects device information through a module.

Although not shown in FIG. 1, there may be a device that relays communication between the server 1000, the first module 100 and the second module 200. For example, another module may exist between the server 1000 and the first module 100, and transmit a communication signal between the server 1000 and the first module 100.

In addition, for example, a sub-server or edge computing may exist between the server 1000 and the first module 100 to transmit communication signals between the server 1000 and the first module 100. That is, the server 1000 and each module may communicate with each other without distance limitations.

According to an embodiment, the server 1000 may include a control unit 1100, a communication unit 1200, a storage unit 1300, and an analysis unit 1400.

FIG. 1 illustrates four components included in the server 1000, but the illustrated components are not essential, and the server 1000 may have more or fewer components. In addition, each component of the server 1000 may be physically included in one server, or may be a distributed server distributed for each function.

The control unit 1100 may control the overall operation of the server 1000. In detail, the control unit 1100 may transmit control commands to the communication unit 1200, the storage unit 1300, and the analysis unit 1400 to execute the operations of each unit.

Unless otherwise specified below, the operation of the server 1000 may be interpreted as being performed under the control of the control unit 1100.

The communication unit 1200 may connect the server 1000 and an external device to communicate. That is, the communication unit 1200 may transmit/receive data to/from an external device. For example, the communication unit 1200 may exchange data with the first module 100 or the second module 200.

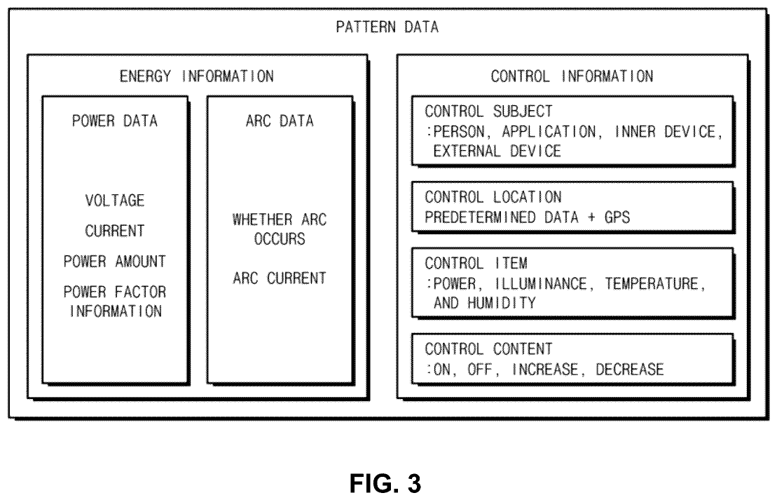

According to an embodiment, the communication unit 1200 may receive energy information of a device connected to the module from the module. For example, the communication unit 1200 may receive energy information of the first device from the first module 100. Hereinafter, the details will be described with reference to FIG. 3.

The communication unit 1200 may be a communication module that supports at least one of a wired communication scheme and a wireless communication scheme. For example, the communication unit may obtain data from an external device through a communication scheme such as WiFi, Bluetooth, Zigbee, Bluetooth low energy (BLE), RFID, or the like.

The storage unit 1300 may store various data and programs necessary for the server 1000 to operate. The storage unit 1300 may store information acquired by the server 1000.

For example, the storage unit 1300 may store information about the energy of the device that the communication unit 1200 receives through the module. In addition, the storage unit 1300 may store information about the control of each device.

The storage unit 1300 may store data temporarily or semi-permanently. The storage unit 1300 may include, for example, a hard disk drive (HDD), a solid state drive (SSD), a flash memory, a read-only memory (ROM), a random access memory (RAM), cloud storage, or the like. However, the storage unit 1300 is not limited to the above and may be implemented with various modules for storing data.

The storage unit 1300 may be provided in a form built into a wearable device 1000 or in a detachable form.

The analysis unit 1400 may analyze data obtained by the communication unit 1200, classify the data, and generate new data. In this case, the analysis unit 1400 may input data into a learned machine learning model and analyze data related to the device. The analysis unit 1400 may analyze the reason for controlling the device at each time point through a machine learning model. The analysis unit 1400 may continuously train the machine learning model through data input to the machine learning model.

According to an embodiment, the analysis unit 1400 may analyze or classify data on the device obtained through the communication unit 1200. In detail, the analysis unit 1400 may analyze or classify information about the energy of the device.

For example, the analysis unit 1400 may analyze the power status of the device by analyzing the voltage, current, power amount, and the like of the device. In addition, the analysis unit 1400 may analyze the arc generation status of the device by analyzing whether an arc occurs in the device and the arc current.

In addition, specifically, the analysis unit 1400 may analyze or classify information about control of the device. For example, the analysis unit 1400 may analyze data on what items, by whom, and how the device is controlled at a time point. In addition, the analysis unit 1400 may classify data on control according to 5W1H.

For a specific example, the analysis unit 1400 may classify device control into control subject, control location, control item, and control content and generate control information according to the classification.

The analysis unit 1400 may generate pattern data including information related to the energy of the device and control information according to classification. In addition, the analysis unit 1400 may later establish a control policy for the device based on the pattern data. The pattern data generated by the analysis unit will be described in detail below with reference to FIG. 3.

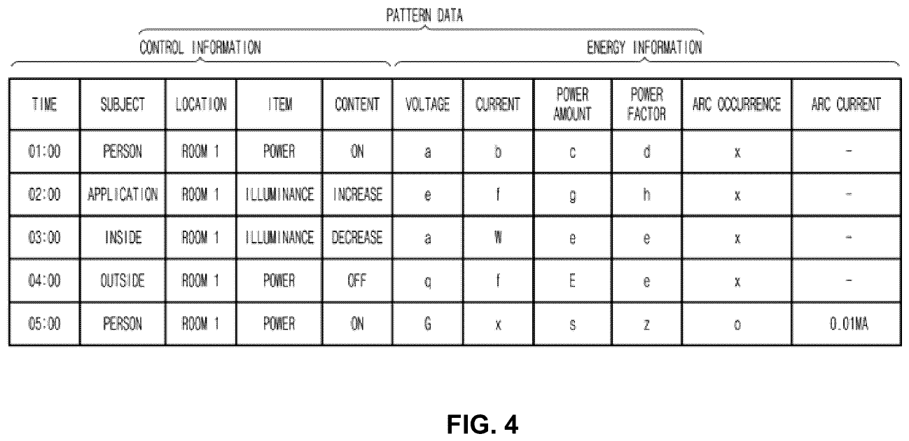

FIG. 3 is a diagram illustrating pattern data generated by a server according to an embodiment. FIG. 4 is a diagram illustrating an example of pattern data according to an embodiment.

Referring to FIG. 3, pattern data may include energy information and control information.

The energy information included in the pattern data, which is related to the energy of the device, may include power data and/or arc data.

As shown in FIG. 4, the power data may include voltage, current, power amount, and/or power factor information of the device, as shown in FIG. 4. The voltage, current, power, and power factor of the device vary with time, and the device transmits the corresponding information that varies with time to the module. The device may transmit the corresponding information to the module in real time, periodically, only when there is a change, or aperiodically at the request of the module.

As shown in FIG. 4, arc data may include information about whether an arc occurs in the device and an arc current when an arc occurs. An arc may occur in the device due to external shock or internal circuit problems. The device may continuously monitor arcing and detect an arc current when an arc occurs. The device may transmit information related to an arc to the module in real time, periodically, only when there is a change, or aperiodically at the request of the module.

The control information included in the pattern data, which is related to the control of the device, may include information related to the control subject, control location, control item, and/or control content.

As shown in FIG. 4, the control subject that controls the device may be a person, an application, an internal device, or an external device. In detail, the device may be controlled by a person operating a switch, an application on a user terminal, a reservation system inside the device, or manipulation by an external device.

In addition, the place where the device is controlled may be the place where the control subject is located, depending on the control subject. In detail, when the control subject is a person, the control location may be a location where the switch is placed, and when the control subject is an application, the control location may be determined based on GPS sensing information of a user terminal. In addition, when the control subject is an internal device, the control location may be a location where the device is located, and when the control subject is an external device, the control location may be a location where the external device is located.

In addition, the control item and content that control the device may vary depending on the type of device. For example, when the device is a heating/cooling device, the control item may be power, temperature, or humidity, and the control content may be on, off, increase, or decrease. In addition, for example, when the device is a lighting device, the control item may be power or illuminance, and the control content may be on, off, increase, or decrease.

Referring to FIG. 4, the server 1000 may generate pattern data according to time. The pattern data in FIG. 4 is pattern data generated by the server 1000 for a lighting device.

For example, the server 1000 may generate pattern data including control information and energy information of the device at the first time point (01:00). In this case, the control information at the first time point may include information about the fact that the person in room 1 turns on the lighting device. In addition, in this case, the energy information at the first time point may include information about the facts that the lighting device has voltage a, current b, power c, and power factor d at the first time, and that no arc occurs.

In addition, the pattern data may include control information and energy information of the device at the second time point (02:00). In this case, the control information at the second time point may include information about the increase in illuminance of the lighting device by the user terminal in room 1. In addition, in this case, the energy information at the second time point may include information about the facts that the lighting device has voltage e, current f, power g, and power factor h at the second time point, and that no arc occurs.

The server 1000 may analyze the pattern data and then establish a policy for building energy. In detail, by analyzing the energy information of the device according to the control information, a policy by which the device is to be controlled at a specific time point may be established. In detail, by analyzing the energy information of the device according to the control information, it is possible to establish a policy by which the device is to be controlled according to a specific control subject.

For example, based on the information included in the pattern data, when the server 1000 determines that the lighting device is turned on by a person at 9 a.m., the server 1000 may set control for the lighting device such that the lighting device is turned on automatically every 9 a.m.

In addition, for example, based on the information included in the pattern data, when the server 1000 determines that the set temperature reduction control is repeatedly performed on the air conditioner after the indoor temperature becomes 25 degrees or higher, the server 1000 may adjust the set temperature such that the indoor temperature does not exceed 25 degrees.

In addition, after establishing a policy, the server 1000 may transmit control commands through a module to each device according to the policy.

For example, the server 1000 may transmit a control command to each module to turn off the lighting device and the air conditioner at 6 PM according to the work leave policy. In this case, each module may control the power of the device connected to each module to be turned off based on the received control command.

In addition, for example, the server 1000 may transmit a control command to each module to set the temperature of the heater to 24 degrees for a time period according to the winter policy. In this case, each module may control to allow the set temperature of the heater connected to each module to be 24 degrees based on the received control command.

When the server 1000 transmits control data including control commands to each module according to policy, the time at which device control is performed may vary depending on the communication scheme of each module. In detail, the first module 100 may communicate with the server 1000 through a first communication scheme, and the second module 200 may communicate with the server 1000 through a second communication scheme that is different from the first communication scheme.

The reason why the communication schemes of the module are different may be due to the device connected to the module. Alternatively, the communication scheme may change depending on where each device is installed. For example, the module connected to an outlet may communicate with the server 1000 through WiFi or Bluetooth, and the module connected to a lighting device may communicate with the server 1000 through ZigBee. In this case, the ZigBee communication scheme may be slower than the Wi-Fi or Bluetooth communication scheme.

Due to differences in communication schemes, even when the server 1000 transmits the same control command to the module, the control performed by the control command may be performed differently for each device.

For example, the server 1000 may transmit control data to the first module connected to the first lighting device and the second module connected to the second lighting device such that the first lighting device and the second lighting device are turned on.

In this case, the first module communicating with the server 1000 in the first communication scheme may change the power of the first lighting device to the on state at the first time point based on the received control data. However, the second module communicating with the server 1000 in the second communication scheme may change the power of the second lighting device to the on state at the second time point, which is later than the first time point, based on the received control data.

From the outside, it may be checked that although the server 1000 transmits control data at the same time, the power of each lighting device is not turned on at the same time but is turned on separately. This may be seen as an error in the building energy management system including the server 1000.

In addition, internally, the server 1000 may be required to process data related to each module with the same timestamp. When the server 1000 processes data related to each module that does not arrive uniformly due to differences in communication speed, the server 1000 may not process the data in batches, so it is necessary to manage it with a single time stamp.

Therefore, a building energy management system that can take into account speed differences in communication schemes is needed. Differences in speed between communication schemes may be resolved by including a delay in the control data.

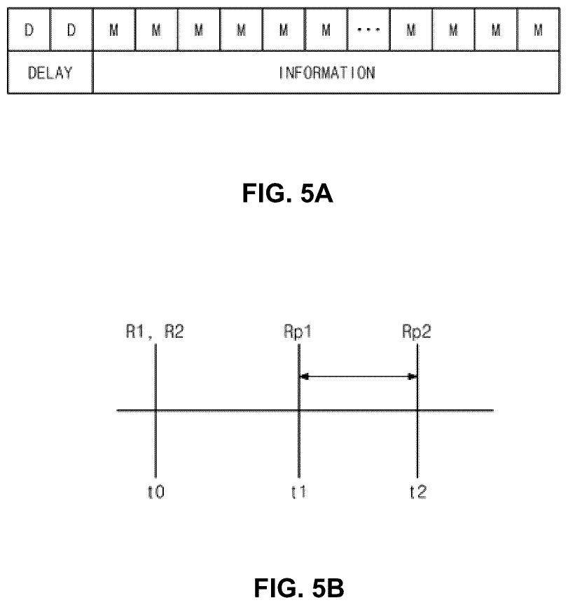

FIG. 5 is a diagram illustrating control data and delay measurement according to an embodiment. FIG. 5A is a diagram illustrating control data, and FIG. 5B is a diagram illustrating an example of measuring delay.

Referring to FIG. 5A, the control data transmitted by the server 1000 to each module may include a delay D and a control command M (information). For example, when the control data is 255 bits, the server 1000 may allocate a delay to 2 bits and control commands to the remaining bits.

When control data including a delay is transmitted to the module, the module may operate in a buffer state for a time corresponding to the delay. That is, the module may not process data for a time corresponding to the delay, but may process data after the time has elapsed. In this case, processing data may mean controlling the device by transmitting control commands to the device.

Referring to FIG. 5B, an example of a method of setting a delay included in control data is illustrated. The server 1000 may transmit a signal to the first module and the second module in advance, determine the time when the signal is received by the module, and set a delay based on the difference in reception time.

For example, the server 1000 may transmit a first reference signal R1 to the first module in a first communication scheme and transmit a second reference signal R2 to the second module in a second communication scheme. In this case, the reference signal may be a basic communication signal that does not include control commands. In addition, the first reference signal R1 may be the same as the second reference signal R2.

In this case, as shown in FIG. 5B, the server 1000 may simultaneously transmit the first reference signal R1 and the second reference signal R2 at a reference time point t0. However, the embodiment is not limited to the above, and the server 1000 may determine the speed difference between the communication schemes of each module in another manner without simultaneously transmitting the first reference signal R1 and the second reference signal R2.

For example, it is possible to transmit the first reference signal R1 at the first time point, receive a response to the first reference signal R1 at a second time point, and determine the speed of the first communication scheme based on the first time point and the second time point. In addition, it is possible to transmit the second reference signal R2 at a third time point, receive a response to the second reference signal R2 at a fourth time point, and determine the speed of the second communication scheme based on the third time point and the fourth time point.

The first module that receives the first reference signal R1 may transmit a first response signal Rp1, which is a response to the first reference signal R1, back to the server 1000. In this case, the first response signal Rp1 may be a simple ACK signal. The server 1000 may receive the first response signal Rp1 at the first time point t1.

The second module that receives the second reference signal R2 may transmit a second response signal Rp2, which is a response to the second reference signal R2, back to the server 1000. In this case, the second response signal Rp2 may be a simple ACK signal. The server 1000 may receive the second response signal Rp2 at the second time point t2.

The server 1000 may calculate the difference between the first time point t1 and the second time point t2. In this case, the difference may mean the speed difference between the first communication scheme and the second communication scheme. The server 1000 may set a delay to be included in control data based on the difference.

In addition, when setting the delay based on the difference, not only the difference in communication speed but also the difference in data processing speed of each module may be reflected.

When transmitting the control data to the first module and the second module simultaneously, the server 1000 may transmit first control data that includes the delay set based on the difference to the first module, and transmit second control data that does not include the delay to the second module.

Alternatively, when the server 1000 controls the first device and the second device simultaneously but does not transmit control data to each module simultaneously, the server 1000 may transmit the first control data that includes the first delay set based on the difference to the first device, and transmit, to the second module, the second control data that includes a time point when the first control data is transmitted, the first delay and the second delay set based on the time when data is to be transmitted to the second module. That is, when the server 1000 does not transmit the control data to each module simultaneously, the server 1000 may transmit the control data to each module while a calculated delay is included in the control data transmitted to each module.

The methods according to the above-described embodiments of the present disclosure may be implemented with program instructions which may be executed through various computer means and may be recorded in computer-readable media. The media may also include, alone or in combination with the program instructions, data files, data structures, and the like. The program instructions recorded in the media may be designed and configured specially for the embodiments of the present disclosure or be known and available to those skilled in computer software. Computer-readable media include magnetic media such as hard disks, floppy disks, and magnetic tape; optical media such as compact disc-read only memory (CD-ROM) disks and digital versatile discs (DVDs); magneto-optical media such as floptical disks; and hardware devices that are specially configured to store and perform program instructions, such as read-only memory (ROM), random access memory (RAM), flash memory, and the like. Program instructions include both machine codes, such as produced by a compiler, and higher level codes that may be executed by the computer using an interpreter. The described hardware devices may be configured to act as one or more software modules to perform the operations of the above-described embodiments of the present disclosure, or vice versa.

While a few embodiments have been shown and described with reference to the accompanying drawings, it will be apparent to those skilled in the art that various modifications and variations can be made from the foregoing descriptions. For example, adequate effects may be achieved even when the foregoing processes and methods are carried out in different order than described above, and/or the aforementioned elements, such as systems, structures, devices, or circuits, are combined or coupled in different forms and modes than as described above or be substituted or switched with other components or equivalents.

Thus, it is intended that the present disclosure covers other realizations and other embodiments of the present disclosure provided they come within the scope of the appended claims and their equivalents.

1. A building energy management system that collects information about a module connected to a device arranged in a building to manage an energy of the building, the building energy management system comprising:
a first module connected to a first device to generate first pattern data including information related to an energy and a control of the first device; and
a server configured to receive the first pattern data from the first module and control the first device through the first module based on the first pattern data,
wherein the first module is configured to:
receive a plurality of time information, and a plurality of energy information and a plurality of control information respectively corresponding to the plurality of time information from the first device,
classify the plurality of control information according to a control subject, a control location, and a control item for operation of the first device, and
generate the first pattern data based on the plurality of energy information and a plurality of classified control information including information related to power of the first device.

2. The building energy management system of claim 1, wherein the control subject includes at least one of a person, an application, an external device, and an internal device of the first device.

3. The building energy management system of claim 1, wherein the control location is set based on sensing information from a GPS sensor included in a device when the control subject is the device.

4. The building energy management system of claim 1, wherein the plurality of time information is determined by internal time information of the first module, and
the internal time information of the first module is periodically or aperiodically synchronized by the server.

5. The building energy management system of claim 1, wherein the control item includes at least one of power, illuminance, temperature, and humidity of the first device.

6. The building energy management system of claim 1, wherein the plurality of energy information includes the plurality of time information and a plurality of power data and arc data respectively corresponding to the plurality of time information,
the plurality of power data includes at least one of voltage, current, power amount, and power factor information of the first device, and
the arc data includes whether an arc occurs in the first device and an arc current.

7. The building energy management system of claim 1, wherein the server is configured to obtain energy information at a first time point, control information at the first time point, energy information at a second time point, and control information at the second time point among data included in the first pattern data, and
input energy information and control information for each time point included in the first pattern data to a machine learning model, and analyze reason for control of the first device for each time point based on the machine learning model.

8. An energy management module that is connected to a device arranged in a building to control the device and collects information about the device to transmit collected information to an external device, the energy management module comprising:
a control processor connected to the device to change a power state of the device or adjust a voltage or a current;
a storage processor configured to store energy information related to an energy of the device and control information for operation of the device; and
a communication processor configured to transmit data including the energy information and the control information to the external device or receive control command data for the device from the external device,
wherein the energy information includes at least one of voltage, current, power amount, and power factor information of the device, and
the control information includes a control subject, a control location, and a control item for the operation of the device.
